(19) United States
(12) Patent Application Publication
(10) Pub. No.: US 2026/0023333 A1
(43) Pub. Date: Jan. 22, 2026

(54) DEVICE FOR ACCOMMODATING OPTICAL ELEMENTS

(71) Applicant: Carl Zeiss SMT GmbH, Oberkochen (DE)

(72) Inventor: Tim Stampe, Berlin (DE)

(21) Appl. No.: 19/273,604

(22) Filed: Jul. 18, 2025

(30) Foreign Application Priority Data
Jul. 22, 2024 (DE) 102024120711.6

(51) Int. Cl. G03F 7/00; G01N 21/95; G02B 7/02

(52) U.S. Cl. CPC G03F 7/70825; G01N 21/9501; G02B 7/028; G03F 7/7095; G03F 7/70975

(57) ABSTRACT

The invention relates to a device for accommodating optical elements of a semiconductor technology apparatus.

The device comprises a plurality of holding elements which extend substantially parallel to one another, are elastically deformable in the manner of a cantilever to their elastic limit, and are formed and arranged in such a way that an optical element is connectable for accommodation purposes to the free ends of the holding elements, wherein at least part of the holding elements are plastically deformable when applying a defined lever force in such a way that the free ends are removed from a previously accommodated optical element.

The invention further relates to an apparatus comprising a device according to the invention, a tool for applying the defined lever force and its use.

### CROSS-REFERENCE TO RELATED APPLICATION

The present application claims the priority of the German patent application DE 2024 120 711.6, filed on Jul. 22, 2024, the entire contents of which are incorporated herein by reference.

### TECHNICAL FIELD

The invention relates to a device for accommodating optical elements of a semiconductor technology apparatus.

### BACKGROUND

Prior-art semiconductor technology apparatuses are understood to mean apparatuses that are used for the production or testing of microstructured component parts or the components required for this purpose. An example of such an apparatus is a photolithographic projection exposure apparatus.

Photolithography is used for producing microstructured component parts, such as for example integrated circuits. The projection exposure apparatus used in the process comprises an illumination system and a projection system. The image of a mask (also referred to as a reticle) illuminated by the illumination system is projected so as to reduce the size of the former onto a substrate, for example a silicon wafer, which is coated with a light-sensitive layer and arranged in the image plane of the projection system, using the projection system in order to transfer the mask structure to the light-sensitive coating of the substrate.

Both in illumination systems and in the projection systems, in particular of projection exposure apparatuses designed for the extreme ultraviolet (EUV) range, i.e. at wavelengths of exposure from 5 nm to 30 nm, as a rule, a plurality of optical elements, in particular mirrors, are provided to achieve the desired imaging of the mask onto the substrate. Due to the required accuracy, it must be ensured, especially in projection systems, that the position of the individual optical elements in relation to one another and in relation to the mask and the substrate during operation of the projection exposure apparatus changes-if at all-only within a specified extent. In addition, the shape of the optical elements, in particular the mirror surfaces, must not change or change only within a specified extent. Any change in the position and/or shape of one or more optical elements beyond the specified extent may result in a decrease in the imaging quality of the projection system.

The same also applies to other systems for semiconductor technology, such as mask inspection devices. Such devices can be used to inspect masks prior to operation in a microlithographic projection exposure apparatus or during an operational interruption in order to detect possible faults or impurities that may lead to a rejection of semiconductors manufactured on the basis of the mask. For this purpose, one or more so-called aerial images of in each case one section of the photomask are generated, which can be examined for faults and impurities. To generate the aerial images, the mask is exposed to radiation at a suitable wavelength by an illumination system and the radiation transformed by the mask is imaged by an optical unit with one or more optical elements onto an image sensor suitable for the selected wavelength. It is also true for the optical unit in mask inspection devices that any change in the position and/or shape of one or more optical elements beyond the specified extent may result in a decrease in the imaging quality of the mask inspection devices, which must be avoided. In order to avoid undesirable deformation and/or changes in position due to different thermal expansions of optical elements and their respective mount, it is known to design the mount for an optical element of an apparatus for semiconductor technology suitably resiliently. One variant of such a mount is the so-called “foot” mount.

The foot mount comprises a plurality of elastically deformable feet, which are, distributed over the circumference, generally materially bonded to the optical element. The feet are formed like a bending spring that is clamped fixedly on one side, so that they bend elastically outwards when the optical element expands, as a result of which neither the optical element is forced in such a way that it deforms, nor does the position change in such a way that, in particular, an optical axis of the optical element shifts.

In order to ensure secure accommodation of an optical element in a foot mount, the individual feet are generally materially bonded to the optical element by means of adhesive bonding. If the optical element must be removed from the mount for correction purposes for example, this bonding can be “deglued,” i.e. the material bond is removed. Depending on the adhesive used, the deglueing can be effected by sufficient heating of the adhesive or by chemical agents that react appropriately with the adhesive. Together with the effect on the adhesive, the respective foot is usually also pulled away from the optical element during the deglueing process by applying force.

After the deglueing, however, the feet of the mount always remain in close contact with the optical element due to their resilient design and are pressed against the optical element due to the spring force. It remains difficult for the optical element to be detached from the mount damage-free due to the continued tight contact between the feet and the optical element.

### SUMMARY

An aspect of the present invention is to provide a device for accommodating optical elements of a semiconductor technology apparatus and to provide a semiconductor technology apparatus in which these disadvantages no longer occur or only to a lesser extent.

This aspect is achieved by a device according to claim 1 and a semiconductor technology apparatus according to claim 14. A tool designed for specific embodiments of the device is the subject of claim 16, the use of which is the subject of claim 19. The holding element used in the device according to the invention also merits separate protection and is the subject of claim 21. The dependent claims relate to advantageous developments.

Accordingly, the invention relates to a device for accommodating optical elements of a semiconductor technology apparatus having a foot mount comprising a plurality of holding elements, which extend substantially parallel to one another, are elastically deformable in the manner of a cantilever up to their elastic limit, and are designed and arranged in such a way that an optical element is connectable to the free ends of the holding elements for accommodating purposes, wherein at least part of the holding elements can be plastically deformed when applying a defined lever force in such a way that the free ends are removed from a previously accommodated optical element.

The invention also relates to a semiconductor technology apparatus comprising at least one optical element, with at least one optical element being accommodated by a device according to the invention.

The invention further relates to a tool for applying a defined lever force to a holding element of a device according to the invention or a semiconductor technology apparatus according to the invention, wherein the tool is formed for a form-fitting connection with the free end of the holding element and for further contact with the holding element removed from the free end of the holding element.

The invention also relates to the use of a tool according to the invention on a device according to the invention or an apparatus according to the invention, wherein, using the tool, a defined lever force is applied to a holding element of a device for accommodating optical elements of a semiconductor technology apparatus in such a way that the holding element deforms plastically in such a way that its free end is removed from a previously accommodated optical element.

Finally, the invention relates to a holding element for cantilever-type clamping, which holding element is elastically deformable up to its elastic limit and whose free end is designed for connection with a superordinate component, wherein the holding element is plastically deformable when applying a defined lever force such that its free end is removed from a previously connected superordinate component.

Firstly, some terms used in connection with the invention are explained.

An element is considered to be “elastically deformable” if it deforms under a load and returns to its original shape after removal of the load. For an elastic deformation, the load must be below the elastic limit, because a load above the elastic limit (also) leads to plastic deformation. The plastic deformation is irreversible in which the deformation remains after removal of the load,

An element is considered to be “cantilever-type” or “like a cantilever” if it is fixedly clamped on one side and its remainder is free, so that the element behaves under load like a cantilever known from technical mechanics.

The invention has recognized that proven foot mounts known from the prior art for optical elements of semiconductor technology apparatuses can be significantly improved with regard to the detachment of an optical element that is accommodated thereby if the holding elements, which are spring-elastic in principle for achieving the advantages of a corresponding foot mount, can also be plastically deformed at least in part if required by applying a defined lever force so that they are no longer in contact with the optical element after this plastic deformation. The removal of the optical element from the device or mount is then much easier. This is especially true if all holding elements can and also will be plastically deformed accordingly.

The elastic limit or the defined lever force with which a holding element can be plastically deformed is to be chosen in such a way that it is not achieved with the ordinary handling of the optical element and/or the device. This ensures that the holding element behaves in principle as known from the prior art regarding foot mounts, as a result of which the known advantages of a corresponding mount are preserved.

In order to achieve the desired plastic deformability of a holding element, provision may be made for a holding element to have a notch. The notch reduces the geometric moment of inertia of the holding element, so that the holding element in this region can be bent more easily and the desired plastic deformation can be achieved more easily. The lever force required for the plastic deformation can be defined by the design of the notch. By providing a notch, the position at which the plastic deformation of a holding element takes place can also be substantially defined.

In order to be able to apply the required defined lever force to a holding element, provision may be made for the free end of a holding element to be designed for a form-fitting connection with a lever tool. If a lever tool is form-fittingly connected to a holding element, the lever tool can also be supported at a distance from the free end of the holding element in order to be able to apply the required leverage force. The holding element may be suitably designed for this purpose. If a notch is provided, the lever tool may preferably lie in the region of the notch, which may also include at least partial engagement in the notch. Here, too, the holding element may be suitably designed for this purpose.

Alternatively, two projecting gripping elements can be arranged at at least one holding element at such a distance from one another that the defined lever force is applied to the holding element by applying substantially opposing forces to the gripping elements. If the two holding elements are “compressed,” for example, by use of pliers, a bending load is thereby introduced into the region of the holding element between the two gripping elements, which bending load results in plastic deformation in this region if a sufficiently large resulting lever force is applied. It is preferred in this case if the two projecting gripping elements are arranged on both sides of a notch, in other words, a notch is therefore provided between the two gripping elements.

It is preferred if adhesive surfaces are formed at the free end of at least a part of the holding elements for forming a material bond with an optical element to be gripped. The device can then be used in a similar way as the known foot mounts. If a holding element connected with a material bond on the adhesive surface to an optical element is to be deglued, the application of a tensile force, which is regularly helpful for deglueing, to the adhesive can be achieved by applying the defined lever force.

It is preferred if at least a part of the holding elements is made of metal, preferably of stainless steel. Thus, if the holding elements are suitably designed, both the elasticity desired in principle of the holding elements and the plastic deformation can be realized when applying the defined lever force.

At least part of the holding elements may have a length of 15 to 25 mm, preferably from 18 to 22 mm, further preferably of about 20 mm.

The device can comprise, for example, 12, 16 or 20 holding elements. As already indicated, it is preferred if all holding elements of the device are designed as described.

For explaining the semiconductor technology apparatus according to the invention, reference is made to the above explanations.

The tool according to the invention is a lever tool, such as has already been mentioned in connection with the particular configuration of the device, in which at least one holding element is formed at the free end for a form-fitting connection with a tool.

In order to be able to apply the required lever force to a correspondingly designed holding element so that it is plastically deformed as desired, the tool is designed for a form-fitting connection with the free end of the holding element and for further contact with the holding element away from the free end of the holding element (or at a distance from the free end of the holding element). Due to the form-fitting connection with the free end of the holding element and simultaneous contact with the holding element away from the free end (or at a distance from the free end), the tool serves as a lever for bending the holding element, usually in the area of contact with the holding element. If there is sufficient force according to the defined lever force, this bending is plastic.

The tool can preferably be formed in the region provided for contact with the holding element for engagement in a notch of the holding element. For example, the tool may have a projection adapted to the position and design of the notch for this purpose. If a corresponding engagement is provided, it can be ensured particularly well that the tool is used properly, since for a correct position of the tool on a holding element not only the form-fitting connection at the free end, but also the engagement in the notch of the holding element is required, which is easy to verify by a user.

The tool may preferably comprise a heating cartridge for the deglueing of the adhesive surface of a holding element. If the tool is suitably equipped, it is possible when it is used that a possible adhesion of the holding element to be detached and the optical element can be heated by the heating cartridge and thereby be deglued, while at the same time the tool can be used to remove the holding element from the optical element, which is helpful for the deglueing.

To explain the use according to the invention of the tool, reference is made to the above embodiments.

The invention also extends to the holding element as such, as is described above in connection with the device for accommodating optical elements. The free end of the holding element, provided that the holding element is fixedly clamped on one side, which corresponds to a cantilever-type clamping, can be designed for connection with any superordinate component. However, due to the plastic deformation of the holding element when applying a defined lever force, it is possible not only to detach this connection, but also to ensure that the free end is removed from the previously connected superordinate component.

The holding element can be further developed according to the holding elements of the device according to the invention for accommodating optical elements, so that the preferred configurations explained above of at least a part of the holding elements of the device according to the invention also apply similarly to the holding element as such, wherein possible references to the device or the optical elements to be accommodated by the device are to be read as being superordinate components on which the holding element can either be clamped or to which the free end of the holding element can be connected.

### BRIEF DESCRIPTION OF DRAWINGS

The invention will now be described by way of example on the basis of advantageous embodiments with reference to the accompanying drawings, in which:

FIG. 1: shows a schematic illustration of an example of a photolithographic projection exposure apparatus;

FIG. 2: shows a schematic illustration of an example of a mask inspection device;

FIGS. 3A and 3B: show schematic illustrations of a first exemplary embodiment of a device according to the invention;

FIGS. 4A to 4D: show schematic illustrations of an example of the use according to the invention of a tool according to the invention on the device according to the invention according to FIG. 3; and

FIGS. 5A and 5B: show schematic illustrations of a second exemplary embodiment of a device according to the invention.

### DETAILED DESCRIPTION

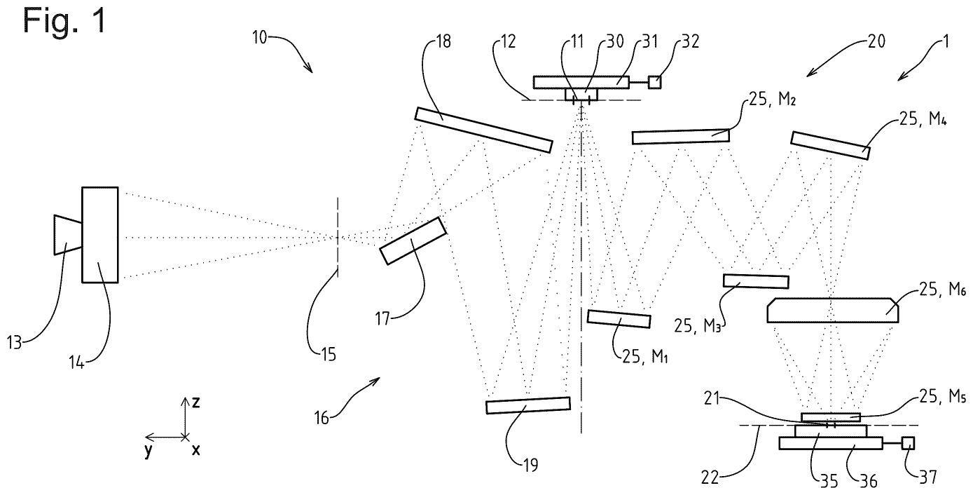

In FIG. 1, a photolithographic projection exposure apparatus 1 is shown in a schematic meridional section as an example of a semiconductor technology apparatus. In this case, the projection exposure apparatus 1 comprises an illumination system 10 and a projection system 20.

An object field 11 in an object plane or reticle plane 12 is illuminated with the aid of the illumination system 10. To this end, the illumination system 10 comprises an exposure radiation source 13, which, in the illustrated exemplary embodiment, emits illumination radiation at least comprising used light in the EUV range, that is to say with a wavelength of between 5 nm and 30 nm in particular. The exposure radiation source 13 can be a plasma source, for example an LPP (laser produced plasma) source or a GDPP (gas discharge produced plasma) source. It may also be a synchrotron-based radiation source. The exposure radiation source 13 can also be a free electron laser (FEL).

The illumination radiation emerging from the exposure radiation source 13 is initially focused in a collector 14. The collector 14 can be a collector with one or with a plurality of ellipsoidal and/or hyperboloidal reflection surfaces. The illumination radiation can be incident on the at least one reflection surface of the collector 14 with grazing incidence (GI), that is to say at angles of incidence of greater than 45°, or with normal incidence (NI), that is to say at angles of incidence of less than 45°. The collector 14 can be structured and/or coated on the one hand for optimizing its reflectivity for the used radiation and on the other hand for suppressing extraneous light.

Downstream of the collector 14, the illumination radiation propagates through an intermediate focus in an intermediate focal plane 15. If the illumination system 10 is constructed in a modular design, the intermediate focal plane 15 can be used, in principle, for the separation-including the structural separation—of the illumination system 10 into a radiation source module, comprising the exposure radiation source 13 and the collector 14, and the illumination optical unit 16 described below. In the case of a corresponding separation, radiation source module and illumination optical unit 16 then jointly form a modularly constructed illumination system 10.

The illumination optical unit 16 comprises a deflection mirror 17. The deflection mirror 17 may be a plane deflection mirror or, alternatively, a mirror with a beam-influencing effect that goes beyond the purely deflecting effect. Alternatively or additionally, the deflection mirror 17 can be embodied as a spectral filter separating a used light wavelength of the illumination radiation from extraneous light having a wavelength that deviates therefrom.

The deflection mirror 17 is used to deflect the radiation emanating from the exposure radiation source 13 to a first facet mirror 18. If—as in the present case—the first facet mirror 18 is arranged in a plane of the illumination optical unit 16 which is optically conjugate to the reticle plane 12 as a field plane, this facet mirror is also referred to as a field facet mirror.

The first facet mirror 18 comprises a multiplicity of micromirrors 18′ that are individually pivotable about two mutually perpendicular axes in each case, for the purpose of controllably forming facets which are each preferably designed with an orientation sensor (not depicted) for ascertaining the orientation of the micromirror 18′. The first facet mirror 18 is thus a microelectromechanical system (MEMS system), as also described in DE 10 2008 009 600 A1, for example.

A second facet mirror 19 is arranged downstream of the first facet mirror 18 in the beam path of the illumination optical unit 16, with the result that this yields a doubly faceted system, the fundamental principle of which is also referred to as a fly's eye integrator. If the second facet mirror 19—as in the depicted exemplary embodiment—is arranged in a pupil plane of the illumination optical unit 16, it is also referred to as a pupil facet mirror. However, the second facet mirror 19 can also be arranged at a distance from a pupil plane of the illumination optical unit 16, as a result of which a specular reflector arises from the combination of the first and the second facet mirror 18, 19, for example as described in US 2006/0132747 A1, EP 1 614 008 B1 and U.S. Pat. No. 6,573,978.

The second facet mirror 19 does not necessarily need to be constructed from pivotable micromirrors, but rather may comprise individual facets formed from one mirror or a manageable number of mirrors which are significantly larger than micromirrors, which facets are either stationary or tiltable only between two defined end positions. It is however—as illustrated—also possible, in the second facet mirror 19, to provide a microelectromechanical system having a multiplicity of micromirrors 19′ that are individually pivotable about two mutually perpendicular axes in each case, each preferably comprising an orientation sensor.

The individual facets of the first facet mirror 18 are imaged into the object field 11 with the aid of the second facet mirror 19, with this regularly only being approximate imaging. The second facet mirror 19 can be the last beam-shaping mirror or else actually the last mirror for the illumination radiation in the beam path upstream of the object field 11.

In each case, one of the facets of the second facet mirror 19 is assigned to exactly one of the facets of the first facet mirror 18 for the purpose of forming an illumination channel for illuminating the object field 11. This may in particular result in illumination according to the Köhler principle.

The facets of the first facet mirror 18 are imaged overlaid on one another by way of a respective assigned facet of the second facet mirror 19, for the purposes of fully illuminating the object field 11. Here, the full illumination of the object field 11 is as homogeneous as possible. It preferably has a uniformity error of less than 2%. Field uniformity can be attained by overlaying different illumination channels.

By selecting the ultimately used illumination channels, which is possible without problems by way of a suitable setting of the micromirrors 18′ of the first facet mirror 18, it is still possible to set the intensity distribution in the entrance pupil of the projection system 20 described below. This intensity distribution is also referred to as illumination setting. Incidentally, it may be advantageous here to arrange the second facet mirror 19 not exactly in a plane that is optically conjugate to a pupil plane of the projection system 20. In particular, the pupil facet mirror 19 can be arranged so as to be tilted relative to a pupil plane of the projection system 20, as is described in DE 10 2017 220 586 A1, for example.

In the arrangement of the components of the illumination optical unit 16 as illustrated in FIG. 1, however, the second facet mirror 19 is arranged in an area conjugate to the entrance pupil of the projection system 20. Deflection mirror 17 and the two facet mirrors 18, 19 are arranged tilted both vis-à-vis the object plane 12 and vis-à-vis one another in each case.

In an alternative embodiment (not illustrated) of the illumination optical unit 16, a transfer optical unit comprising one or more mirrors can additionally be provided in the beam path between the second facet mirror 19 and the object field 11. The transfer optical unit may in particular comprise one or two normal-incidence mirrors (NI mirrors) and/or one or two grazing-incidence mirrors (GI mirrors). Using an additional transfer optical unit, it is possible in particular to take account of different poses of the entrance pupil for the tangential and for the sagittal beam path of the projection system 20 described below.

It is alternatively possible for the deflection mirror 17 depicted in FIG. 1 to be dispensed with, for which purpose the facet mirrors 18, 19 should then be suitably arranged vis-à-vis the radiation source 13 and the collector 14.

The object field 11 in the reticle plane 12 is transferred to the image field 21 in the image plane 22 with the aid of the projection system 20.

To this end, the projection system 20 comprises a plurality of mirrors Mᵢ, which are consecutively numbered in accordance with their arrangement in the beam path of the projection exposure apparatus 1. The mirrors Mᵢ are optical elements 25.

In the example depicted in FIG. 1, the projection system 20 comprises six mirrors M₁ to M₆ as optical elements 25. Alternatives with four, eight, ten, twelve or any other number of mirrors M₁ are likewise possible. The penultimate mirror M₅ and the last mirror M₆ each have a passage opening for the illumination radiation, as a result of which the depicted projection system 20 is a doubly obscured optical unit. The projection system 20 has an image-side numerical aperture that is greater than 0.3 and can also be greater than 0.6, and can be for example 0.7 or 0.75.

The reflection surfaces of the mirrors M₁ can be in the form of freeform surfaces without an axis of rotational symmetry. However, the reflection surfaces of the mirrors M₁ can alternatively also be designed as aspherical surfaces with exactly one axis of rotational symmetry of the reflection surface shape. Just like the mirrors of the illumination optical unit 16, the mirrors M₁ can have highly reflective coatings for the illumination radiation. These reflective coatings can be designed as multilayer coatings, in particular with alternating layers of molybdenum and silicon.

The projection system 20 has a large object-image offset in the y-direction between a y-coordinate of a center of the object field 11 and a y-coordinate of the center of the image field 21. This object-image offset in the y-direction can be of approximately the same magnitude as a z-distance between the object plane 12 and the image plane 22.

In particular, the projection system 20 can be designed to be anamorphic, that is to say it has different imaging scales βₓ, β_{y} in the x- and y-directions in particular. The two imaging scales βₓ, β_{y} of the projection system 20 are preferably (βₓ, β_{y})=(+/−0.25, +/−0.125). An imaging scale β of 0.25 corresponds here to a reduction with a ratio 4:1, while an imaging scale β of 0.125 results in a reduction with a ratio of 8:1. A positive sign in the case of the imaging scale β means imaging without image inversion; a negative sign means imaging with image inversion.

Other imaging scales are likewise possible. Imaging scales βₓ, β_{y} with the same sign and the same absolute magnitude in the x- and y-directions are also possible.

The number of intermediate image planes in the x-direction and in the y-direction in the beam path between the object field 11 and the image field 21 can be the same or different, depending on the embodiment of the projection system 20. Examples of projection systems 20 with different numbers of such intermediate images in the x-direction and y-direction are known from US 2018/0074303 A1.

In particular, the projection system 20 can comprise a homocentric entrance pupil. The latter can be accessible. However, it can also be inaccessible.

A reticle 30 (also referred to as mask) arranged in the object field 11 is exposed by the illumination system 10 and transferred by the projection system 20 onto the image plane 21. The reticle 30 is held by a reticle holder 31. The reticle holder 31 is displaceable by way of a reticle displacement drive 32 in particular in a scanning direction. In the exemplary embodiment illustrated, the scanning direction runs in the y-direction.

The reticle 30 can have an aspect ratio of between 1:1 and 1:3, preferably between 1:1 and 1:2, and particularly preferably of 1:1 or 1:2. The reticle 30 can be substantially rectangular and is preferably 5 to 7 inches (12.70 to 17.78 cm) long and wide, further preferably 6 inches (15.24 cm) long and wide. As an alternative thereto, the reticle 30 can have a length of 5 to 7 inches (12.70 cm to 17.78 cm) and a width of to 14 inches (25.40 cm to 35.56 cm), preferably a length of 6 inches (15.24 cm) and a width of 12 inches (30.48 cm).

A structure on the reticle 30 is imaged onto a light-sensitive layer of a wafer 35 disposed in the region of the image field 21 in the image plane 22. The wafer 35 is held by a wafer holder 36. The wafer holder 36 is displaceable by way of a wafer displacement drive 37 in particular along the y-direction. The displacement on the one hand of the reticle 30 by way of the reticle displacement drive 32 and on the other hand of the wafer 35 by way of the wafer displacement drive 37 may be synchronized with one another.

The projection exposure apparatus 1 shown in FIG. 1 or the projection system thereof, the above description of which reflects substantially known prior art, is characterized in that at least one of the optical elements 25 is accommodated by a device 100 according to the invention.

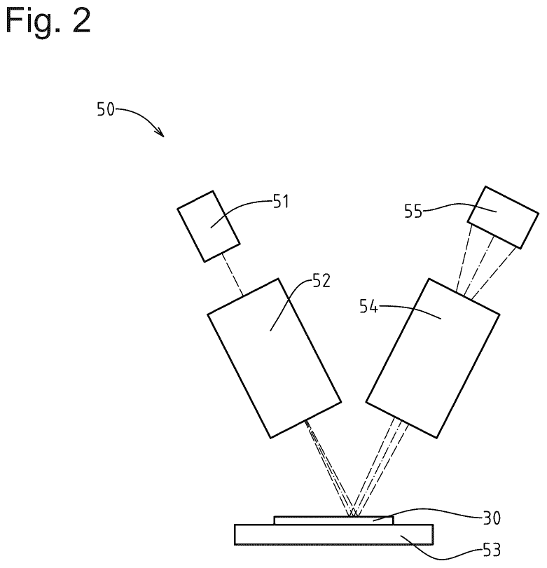

In FIG. 2, a mask inspection device 50 is shown as a further example of a semiconductor technology apparatus. With the mask inspection device 50, a reticle 30, as is also used in the projection exposure apparatus 1 according to FIG. 1, can be examined for faults and impurities.

The mask inspection device 50 comprises a radiation source 51 for radiation having a wavelength matched to the reticle 30. In the present exemplary embodiment, the wavelength of the radiation source 51—since the reticle 30 to be examined is an EUV reticle—is 13.5 nm. The radiation source 51 may in particular be a plasma radiation source whose plasma is based on tin.

The radiation emanating from the radiation source 51 is shaped in an illumination system 52, which comprises various optical elements (mirrors, stops, etc.; not shown), in order to optimally illuminate a portion of the reticle 30.

The illuminated portion can, for example, have a size of 0.5 mm×0.8 mm, while the edge length of the reticle 30 is regularly between 100 mm and 200 mm. In order to be able to inspect all regions of the reticle 30, the reticle 30 is arranged on a stage 53, with which the reticle 30 can be displaced in such a way that a desired region of the reticle 30 is located in the portion illuminated by the radiation source 51 and the illumination system 52.

The radiation reflected at the reticle 30 is imaged, magnified, via a projection lens 54 comprising optical elements (not shown) onto an image sensor 55, which can thus provide a digital image representation of the illuminated portion of the reticle 30. Projection lens 54 or its optical elements, such as in particular mirrors, and image sensor 55 are adapted to the wavelength of the radiation source 51.

The mask inspection device 50 shown is characterized in that at least one optical element of the illumination system 52 and/or the projection lens 54 is accommodated by a device 100 according to the invention.

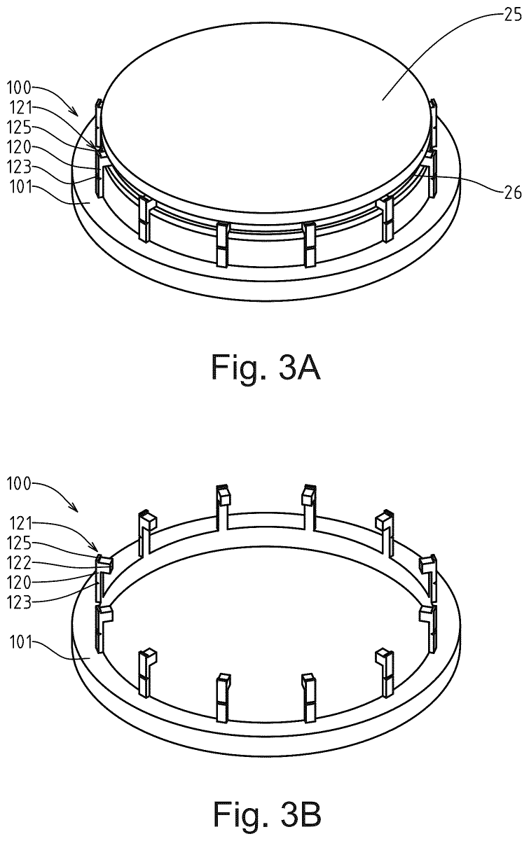

In FIGS. 3A and 3B (collectively referred to as FIG. 3), a device 100 according to the invention for accommodating an optical element 25, as can be used in the projection exposure apparatus 1 according to FIG. 1 or the mask inspection device 50 according to FIG. 2, is shown as an example. FIG. 3A shows a first exemplary embodiment of the device 100 with an optical element 25 accommodated therein, while FIG. 3B shows the device 100 alone.

The device 100 serves to accommodate an optical element 25 of a semiconductor technology apparatus according to the principle of a foot mount. For this purpose, starting from a mount ring 101, a plurality (in the illustrated exemplary embodiment twelve) of holding elements 120 extending substantially relative to one another, but also to the axis of the mount ring 101 are provided. The holding elements 120 can be considered fixedly clamped on one side due to their one-piece configuration with the mount ring 101, so that they ultimately project from the mount ring 101 in the manner of a cantilever.

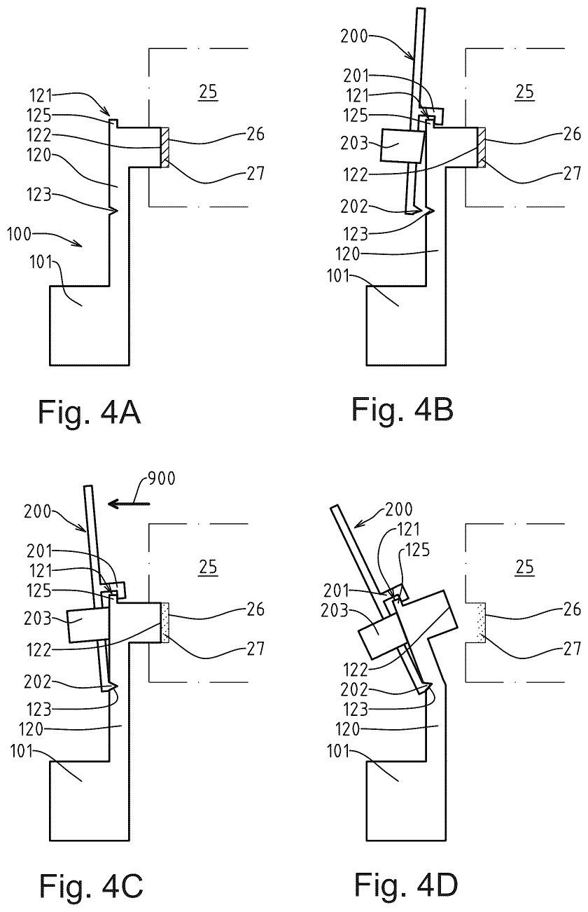

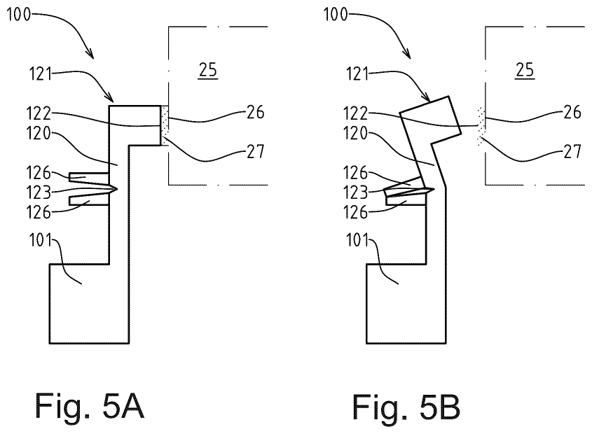

At their free end 121, the holding elements 120 each have a projecting adhesive surface 122, which-if present—is provided for engaging in a circumferential adhesive groove 26 of the optical element 25, but in any case for the materially bonded connection therewith by use of adhesive 27 (cf. FIGS. 4 and 5).

The total height of the individual holding elements 120 is, e.g., 20 mm. The mount ring 101 and the holding elements 120 formed in one piece therewith are made of, e.g., stainless steel. Consequently, the holding elements 120 have an elastic deformability up to their elastic limit, as a result of which the device 100 is in principle comparable with a foot mount known from the prior art.

However, in deviation from the known foot mount, the holding elements 120 are formed in such a way that they deform plastically when applying a defined lever force in such a way that their free ends 121 and in particular the adhesive surfaces 122 are removed from the optical element 25 and in particular no longer project into a possibly circumferential adhesive groove 26.

In order to enable this deformation or to define the required lever force, the holding elements 120 have a notch 123, with which the geometric moment of inertia of the holding element 120 in this region is changed in such a way, that a plastic deformation of the holding element 120 can be achieved at a defined lever force that can be derived from the geometric moment of inertia.

In the exemplary embodiment of the device 100 shown in FIG. 3, the respective free end 121 of the holding elements 120 is designed for a form-fitting connection with a tool 200. For this purpose, each holding element 120 has at its free end 121 a projection 125, which a tool 200 can engage behind in order to achieve a sufficient form-fitting connection.

In the merely schematic FIGS. 4A to 4D (collectively referred to as FIG. 4), a holding element 120 of the device 100 from FIG. 3 is shown isolated in section and in interaction with a tool 200.

FIG. 4A shows the holding element 120 in the initial state, as it is also shown in FIG. 3A, i.e. in a state connected with a material bond to the optical element 25 by adhesive 27 on its adhesive surface 122. In addition, the notch 123 and the projection 125 are shown at the free end of the holding element 120.

FIG. 4B shows how a tool 200 for applying the defined lever force for plastically deforming the holding element 120 is attached.

The tool 200 is designed as an elongated lever on which a hook element 201 is provided for gripping the projection 125 at the free end 121 of the holding element 120 in order to achieve the required form fit using it.

Furthermore, the tool 200 at its one end comprises a projection 202, which is designed for engagement in the notch 123 of the holding element 120. The distance between the hook element 201 and the projection 202 is chosen such that when the tool 200 or hook element 201 and the holding element 120 or projection 125 are connected in a form fit, the projection 202 on the tool 200 engages in the notch 123 of the holding element 120.

The tool 200 also comprises a heating cartridge 203. The heating cartridge 203 is arranged and formed such that, after the initial “hooking” of the tool 200 by its hook element 201 at the projection 125 at the free end 121 of the holding element 120 (cf. FIG. 4B) and the subsequent pivoting of the tool 200 such that the projection 202 thereof engages in the notch 123, it is in contact with the holding element 120 in such a way that it can heat the holding element 120 in the region of the adhesive surface 122. Using the heating cartridge 203, the adhesive surface 122 and the adhesive 27 adhering thereto can be heated such that the materially bonded connection created by the adhesive 27 is at least weakened, i.e. the holding element 120 is deglued. In FIG. 4C, this is indicated by the altered hatching of the adhesive 27.

If the materially bonded connection created by the adhesive 27 is sufficiently weakened by the heat introduced using the heating cartridge 203, the holding element 120 can be bent away from the optical element 25 by applying a force to the tool 200 in the direction indicated by the arrow 900, wherein the holding element 120 is plastically deformed in the region of the notch 123. The lever force required for the plastic deformation is applied to the holding element 120 using the tool 200.

If all holding elements 120 of the device 100 (cf. FIG. 3) according to the use of the tool 200 illustrated in FIG. 4 are permanently bent away from the optical element 25, the optical element 25 can be easily removed from the device 100 without damage.

In FIGS. 5A and 5B (collectively referred to as FIG. 5), an alternative configuration of the holding elements 120 of the device 100 according to FIG. 3 is shown. The holding element 120 is largely formed like the holding element 120 already explained above, and so reference is made to these embodiments. In the following text, only the differences between the two embodiment variants of the holding elements 120 will be discussed. It should also be noted that in the exemplary embodiment according to FIG. 5, the optical element 25 does not have a groove 26 (cf. FIGS. 3 and 4), but the adhesive connection between the holding element 120 and the optical element 25 is effected directly at the circumferential outer surface of the optical element 25.

In the holding element 120 according to FIG. 5, no projection 125 is provided at the free end 121 of the holding element 120. As a result, the tool 200 shown in FIG. 4 is not intended for use with the holding element 120 according to FIG. 5.

For this purpose, the holding element 120 has two projecting gripping elements 126, which are spaced apart from one another, arranged on both sides of the notch 123.

If the adhesive connection between the holding element 120 and the optical element 25 is already deglued or at least sufficiently weakened due to a heat supply not shown in detail or due to chemical processes (cf. FIG. 5A), it is possible by applying opposing forces to the gripping elements 126, for example using pliers, to apply a sufficient lever force to the holding element 120 in the region of the notch 123 such that the holding element 120 is plastically deformed and bent away from the optical element 25.

A number of embodiments of the invention have been described. Nevertheless, it will be understood that various modifications can be made without departing from the spirit and scope of the invention. For example, each holding element 20 can have two or more notches 123 and two or more pairs of gripping elements 126. Two or more tools can be used to plastically deform the holding element, in which each tool is connected to the holding element in a form fit while engaging with one of the notches 123.

While some embodiments, examples or aspects described herein include some but not other features included in other embodiments, examples or aspects combinations of features of different embodiments, examples or aspects are meant to be within the scope of the claims, and form different embodiments, as would be understood by those skilled in the art. The embodiments of the present invention that are described in this specification and the optional features and properties respectively mentioned in this regard should also be understood to be disclosed in all combinations with one another. The description of a feature comprised by an embodiment-unless explicitly explained to the contrary-should also not be understood such that the feature is essential or indispensable for the function of the embodiment. Accordingly, other embodiments are within the scope of the following claims.

What is claimed is:

1. A device for accommodating optical elements of a semiconductor technology apparatus having a foot mount, the device comprising:
a plurality of holding elements which extend substantially parallel to one another, are elastically deformable in the manner of a cantilever to their elastic limit, and are formed and arranged in such a way that an optical element can be connected for accommodation purposes to the free ends of the holding elements,
wherein at least part of the holding elements can be plastically deformed when applying a defined lever force in such a way that the free ends are removed from a previously accommodated optical element.

2. The device of claim 1,
wherein at least a part of the holding elements has a notch, around which the holding element is plastically deformed when applying the defined lever force.

3. The device of claim 1,
wherein the free end of at least one holding element is designed for a form-fitting connection with a tool.

4. The device of claim 3,
wherein the holding element is designed for further contact of the tool at a distance from the free end of the holding element.

5. The device of claim 4,
wherein the holding element is designed for the further contact of the tool in the region of the notch.

6. The device of claim 1,
comprising two projecting gripping elements that are arranged spaced apart from one another at at least one holding element in such a way that the defined lever force is applied to the holding element by applying substantially opposing forces to the gripping elements.

7. The device of claim 6,
wherein the two projecting gripping elements are arranged on both sides of a notch.

8. The device of claim 1,
comprising adhesive surfaces that are formed at the free end of at least a part of the holding elements for a materially bonded connection with an optical element to be accommodated.

9. The device of claim 1,
wherein at least a part of the holding elements is made of metal, preferably stainless steel.

10. The device of claim 9,
wherein at least a part of the holding elements is made of stainless steel.

11. The device of claim 1,
wherein at least part of the holding elements have a length of 15 to 25 mm.

12. The device of claim 11,
wherein at least part of the holding elements have a length of 18 to 22 mm.

13. The device of claim 12,
wherein at least part of the holding elements have a length of approx. 20 mm.

14. A semiconductor technology apparatus comprising at least one optical element, wherein the at least one optical element is accommodated by a device according to claim 1.

15. The apparatus of claim 14,
wherein the apparatus is a photolithographic projection exposure apparatus or a mask inspection device.

16. A tool for applying a defined lever force to a holding element of a device according to claim 1 or a semiconductor technology apparatus comprising at least one optical element, wherein the at least one optical element is accommodated by a device according to claim 1,
wherein the tool is formed for a form-fitting connection with the free end of the holding element and for further contact with the holding element at a distance from the free end of the holding element.

17. The tool of claim 16,
wherein the tool is formed as a further contact with the holding element for engaging in a notch of the holding element.

18. The tool of claim 16,
wherein the tool comprises a heating cartridge for the deglueing of the adhesive surface of a holding element.

19. A method comprising: using a tool according to claim 16 on a device for accommodating optical elements of a semiconductor technology apparatus having a foot mount, the device comprising:
a plurality of holding elements which extend substantially parallel to one another, are elastically deformable in the manner of a cantilever to their elastic limit, and are formed and arranged in such a way that an optical element can be connected for accommodation purposes to the free ends of the holding elements,
wherein at least part of the holding elements can be plastically deformed when applying a defined lever force in such a way that the free ends are removed from a previously accommodated optical element,
comprising when using the tool, a defined lever force is applied to a holding element of a device for accommodating optical elements of a semiconductor technology apparatus in such a way that the holding element deforms plastically in such a way that its free end is removed from a previously accommodated optical element.

20. The method of claim 19,
wherein the holding element is deglued from the optical element before applying the defined lever force.

21. A holding element for cantilever-type clamping, which is elastically deformable up to its elastic limit and whose free end is formed for connection with a superordinate component,
wherein the holding element is plastically deformable when applying a defined lever force in such a way that its free end is removed from a previously connected superordinate component.

22. The holding element of claim 21,
wherein at least a part of the holding element has a notch, around which the holding element is plastically deformed when applying the defined lever force.
